(19) United States
(12) Patent Application Publication
(10) Pub. No.: US 2026/0367143 A1
(43) Pub. Date: Nov. 19, 2026

(54) PROBE HEAD WITH AIR COOLING SYSTEM

(71) Applicant: TECHNOPROBE S.P.A., Cernusco Lombardone (LC) (IT)

(72) Inventor: Raffaele VALLAURI, Cernusco Lombardone (LC) (IT)

(73) Assignee: TECHNOPROBE S.P.A., Cernusco Lombardone (LC) (IT)

(21) Appl. No.: 19/136,606

(22) PCT Filed: Dec. 13, 2023
(86) PCT No.: PCT/EP2023/085510

§ 371 Date: Jun. 6, 2025

(30) Foreign Application Priority Data
Dec. 21, 2022 (IT) 102022000026187

(51) Int. Cl. G01R 31/28

(52) U.S. Cl. CPC G01R 31/2891

(57) ABSTRACT

A probe head for testing a device under test includes a plurality of contact probes having a body with first and second end portions adapted to contact respective pads, a guide provided with guide holes for housing portions of the contact probes and a housing having a body configured to contain the contact probes. The housing includes conveying means for conveying an air flow adapted to facilitate a heat dissipation inside the probe head, and the conveying means includes at least one input duct configured to receive the air flow and to allow conveying the air flow into the housing, and at least one output duct configured to cause the air flow to flow out of the housing, wherein the input ducts and output ducts are formed in the body of the housing.

### FIELD OF APPLICATION

The present invention relates to a probe head adapted to perform the test of electronic devices integrated on a semiconductor wafer. The following description is made with reference to this field of application with the sole aim of simplifying the exposure thereof.

### PRIOR ART

As it is well known, a probe head is essentially a device adapted to electrically connect a plurality of pads of a microstructure, in particular an electronic device integrated on a semiconductor wafer, with corresponding channels of a testing apparatus that performs the functionality testing thereof.

The test, which is performed on integrated devices, is particularly useful for detecting and isolating defective devices as early as in the production phase. Usually, probe heads are therefore used for the electrical test of devices integrated on a wafer or chip before cutting and assembling them inside a chip containment package.

A probe head essentially comprises a plurality of contact probes held by at least one pair of supports or guides which are substantially plate-shaped and parallel to each other. Said plate-shaped supports are equipped with suitable guide holes and are arranged at a certain distance from each other in order to leave a free space or air gap for the movement and possible deformation of the contact probes, which are typically formed by wires of special alloys with good electric and mechanical properties.

The contact probes generally extend between a first end portion, intended to contact the pads of the device under test, and a second end portion, intended to contact the pads of a space transformer or of a printed circuit board (also known as PCB).

The proper operation of a probe head is basically linked to two parameters: the vertical movement (overtravel) of the contact probes and the horizontal movement (scrub) of the contact tips of said probes onto the pads during the contact with the device under test. All these features should be evaluated and calibrated in the manufacturing step of a probe head, and the proper electrical connection between contact probes and device under test should always be ensured.

In the probe heads of the above type, and in the probe cards housing said probe heads, in case of tests at high temperatures, the thermal expansions of the components thereof can undermine their correct behaviour, due to the different thermal expansion coefficients of the different materials which said elements are made up of. It is indeed common to fasten the elements that make up a probe head and the related probe card through screws, which, in particular during a test temperature, apply to the several plates a bond which tends to cause them to buckle, resulting in a malfunction of the probe head as a whole. This problem is particularly felt in the case of large probe heads, such as for instance the probe heads for the test of memory devices such as the DRAMs, or in general the probe heads for the multi-dice test. For this kind of probe heads, indeed, failure to control the thermal expansion of the components leads to considerable problems in the testing phase.

Moreover, during the test operations, a large quantity of heat is generated by the components of the probe head itself; for instance, the contact probes may heat up due to the passage of the several signals, thus increasing the heat present inside the probe head, in particular in case of a probe head equipped with a very high number of contact probes, and still more particularly in the case of power probes. Analogously, the abutment of the contact probes onto the pads of the space transformer and of the device under test and the friction with the walls of the guide holes produce unwanted heat that accumulates, therefore there is the need of limiting the heating of the probe head.

The technical problem of the present invention is to provide a probe head having such structural and functional features as to allow overcoming the limitations and drawbacks still affecting the known solutions, in particular able to optimize the heat dissipation process therein.

### SUMMARY OF THE INVENTION

The solution idea underlying the present invention is to use a forced air flow to facilitate the heat dissipation inside a probe head, wherein said forced air flow is conveyed into the areas of interest by means of a suitable conformation of the housing. In particular, the housing itself comprises suitable channels (namely input and output ducts), which are able to convey the air flow (which comes from an outer source) toward areas of the probe head that are to be cooled, in particular toward areas of a guide that houses the contact probes. The above channels formed in the housing force the air flow to follow a direction that is substantially parallel to the guide. All this ensures a compact structure and an optimal dispersion of the heat generated inside the probe head.

Based on this solution idea, the above technical problem is solved by a probe head for the testing of devices under test, comprising a a plurality of contact probes comprising a body extending along a longitudinal axis between a first end portion and a second end portion, said end portions being adapted to contact respective pads, at least one guide equipped with guide holes for housing portions of the contact probes, said guide lying in a plane, and a housing comprising a body configured to contain the contact probes. According to the invention, the housing comprises conveying means for conveying an air flow adapted to facilitate a heat dissipation inside the probe head, said conveying means including at least one input duct configured to receive the air flow and to allow conveying said air flow into the housing, and at least one output duct configured to cause the air flow to flow out of the housing, wherein the input and output ducts are directly formed in the body of the housing.

More particularly, the invention comprises the following additional and optional features, taken singularly or in combination if needed.

According to an aspect of the present invention, the input duct and the output duct may be oriented so that the air flow propagates inside the housing according to a flow direction which is substantially parallel to the plane of the guide.

According to an aspect of the present invention, the probe head may comprise, for each input duct, at least two output ducts so that the air flow exiting from the housing is divided into at least two flow portions.

According to an aspect of the present invention, the probe head may further comprise a heat dissipation element adapted to collect and dissipate the heat produced by said probe head, said heat dissipation element being arranged so that the air flow of the conveying means passes at the same, said air flow thus facilitating the dissipation of the heat exchanged by the heat dissipation element.

According to an aspect of the present invention, the heat dissipation element may comprise at least one layer of high thermal conductivity material selected from diamond, silicon carbide and silver-diamond compound with a diamond percentage between 50 and 99%, preferably diamond.

According to an aspect of the present invention, the heat dissipation element (in particular the layer of high thermal conductivity material) is one of:
a coating layer arranged along at least part of at least one face of the guide; or
a guide covering layer comprising at least one lateral portion extending along a lateral wall of said guide and at least one planar portion extending along at least part of at least one face of the guide, said face being substantially orthogonal to said lateral wall; or
a coating layer associated with the housing.

According to an aspect of the present invention, the contact probes may be included in at least one first area or active area of the guide, said active area being contiguous to a second area of the guide, said second area not including the contact probes.

According to an aspect of the present invention, the heat dissipation element (in particular the layer of high thermal conductivity material) may extend in at least one part of the second area.

According to an aspect of the present invention, the conveying means may be configured to convey the air flow so as to hit the layer of high thermal conductivity material at said at least one part of the second area.

According to an aspect of the present invention, the guide may comprise a plurality of distinct active areas, each of said active areas comprising respective contact probes and being configured for testing a respective die.

In particular, said active areas may be arranged to allow a multi-die test in parallel, wherein each of said active areas corresponds to a respective die (or chip) under test, and wherein the input duct comprises a plurality of input sub-ducts adapted to divide the input air flow and to convey the same toward a respective active area, the number of input sub-ducts being selected based on the number of dices to be tested by the probe head.

According to an aspect of the present invention, the active areas may be arranged on the guide along respective rows and columns in a matrix configuration, for instance a 4×4 matrix.

According to an aspect of the present invention, the guide may be a lower guide (but not necessarily).

According to an aspect of the present invention, the probe head may further comprise an upper guide separated from the lower guide and provided with respective guide holes, the housing being arranged between the lower guide and the upper guide.

According to an aspect of the present invention, the input duct may comprise a first portion and a second portion angled toward each other, the first portion being adapted to connect to an external source wherefrom the air flow comes, the second portion being in communication with an internal portion of the housing (namely with the inside of the housing, in which the contact probes are present).

According to an aspect of the present invention, the input ducts and the output ducts may extend from consecutive sides (faces) of the body of the housing.

According to an aspect of the present invention, the input and output ducts and may be substantially orthogonal to each other in the plane of the guide, at least in relation to portions thereof lying in said plane.

According to an aspect of the present invention, the body of the housing may be in the shape of a monobloc, wherein the input and output ducts are formed in said monobloc and comprise portions formed integrally therewith.

The features and advantages of the probe head according to the invention will become apparent from the following description of an embodiment thereof, given by way of indicative and non-limiting example, with reference to the attached drawings.

### BRIEF DESCRIPTION OF THE DRAWINGS

In these drawings:

FIG. 1 schematically shows a probe head according to the present invention;

FIG. 2 is a perspective view of a housing in according to embodiments of the present invention;

FIG. 3A shows the housing of FIG. 2 and an air flow which propagates therein, and FIG. 3B shows a fluid dynamics simulation of the air flow inside the housing;

FIG. 4 shows a layout example of a guide of a probe head according to embodiments of the present invention; and

FIGS. 5 to 7 show a probe head according to various embodiments of the present invention.

### DETAILED DESCRIPTION

With reference to these figures, reference number 20 globally and schematically indicates a probe head made according to the present invention.

It should be noted that the figures represent schematic views and are not drawn to scale, but instead they are drawn so as to enhance the important features of the invention. Furthermore, in the figures, the different elements are depicted in a schematic manner, their shape varying depending on the desired application. It is also worth noting that in the figures the same reference numbers refer to elements that are identical in shape or function. Finally, particular features described in relation to an embodiment illustrated in a figure are also applicable to the other embodiments illustrated in the other figures.

Moreover it is noted that, unless expressly indicated, process phases may also be reversed if needed.

The probe head 20 is adapted to connect (directly or indirectly through a space transformer and/or a PCB) with an apparatus (not illustrated in the figures) to perform the test of electronic devices 23 that are integrated on a semiconductor wafer 23′, for instance (but not necessarily) high frequency devices or large-sized memory devices.

It is noted that, in the context of the present invention, the term “probe head” is used to indicate a test device without this being limited by the presence or not of particular components, in addition to what is defined in the attached claims. In general, said term thus indicates an assembly of components associable with further components for testing electronic devices 23 integrated on the aforementioned semiconductor wafer 23′, and thus in general it indicates a measurement system of electronic devices.

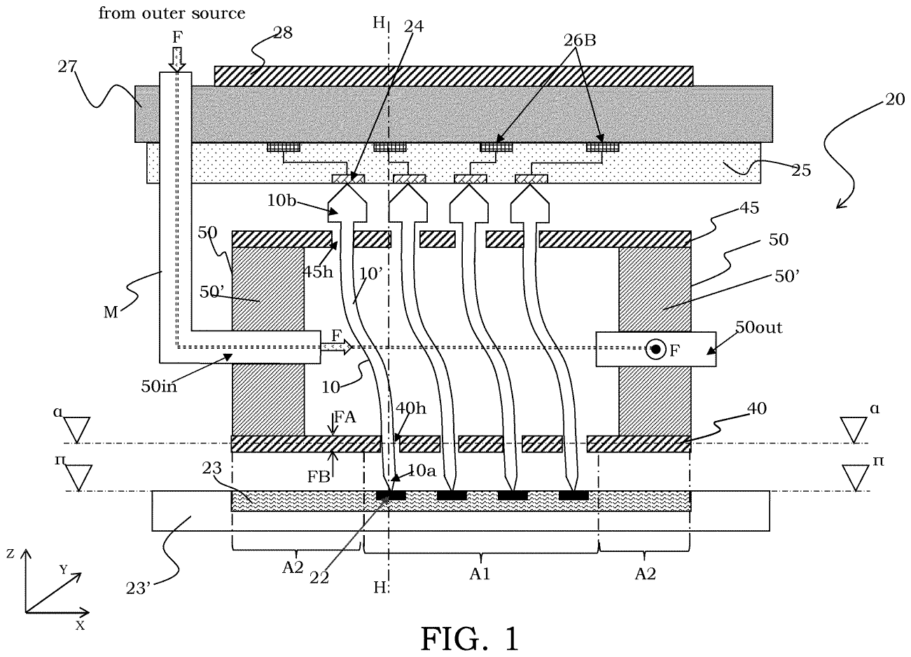

With reference to the sectional view of FIG. 1, the probe head 20 comprises a plurality of contact probes 10 intended to connect the device under test 23 integrated in the semiconductor wafer 23′ with the testing apparatus.

In order to house the contact probes 10, the probe head 20 comprises at least one guide 40 equipped with guide holes 40h within which said contact probes 10 are able to slide. The guide 40 thus allows, along with the guide holes 40h thereof, slidingly housing the contact probes 10.

Each contact probe 10 comprises a probe body 10′ extending along a longitudinal axis H-H between a first end portion 10a and a second end portion 10b, which are adapted to contact pads. By way of example, the first end portion 10a (also called contact tip) is adapted to contact pads 22 of the device under test 23 integrated on the semiconductor wafer 23′, whereas the second and opposite end portion 10b (also called contact head) is adapted to contact pads 24 of a space transformer or of a printed circuit board (PCB) associable with the probe head 20, said component being generically identified with reference number 25. Clearly, though the end portions 10a and 10b in the enclosed figures end with a pointed shape, they are not limited thereto and may have any shape suitable for the needs and/or circumstances. Likewise, though the end portion 10b has an enlarged shape, said configuration only exemplifies the present invention without limiting it.

During the bending of the contact probes 10 (in particular during their vertical movement, indicated in the field as “overtravel”), a sliding contact occurs between probe body 10′ and one or more walls of the guide hole. The probe body 10′ thus comprises a portion intended to be at least partially inserted into a guide hole 40h of the guide 40 of the probe head 20 and, during the movement of the contact probe 10, it performs a contact with said guide hole 40h, in particular a sliding contact.

In the shown examples, the guide 40 is a lower guide of the probe head 20 and thus, as known in the field, it is close to the first end portion 10a intended to contact the device under test, namely it is closer to the device under test during the test with respect to an upper guide or to an intermediate guide. In the examples of the present description, the guide 40 will thus be also identified as lower guide of the probe head 20, however without limiting the scope of the present invention.

In an embodiment, the probe head 20 may also comprise an intermediate guide (not illustrated in the figures) equipped with respective guide holes, wherein the lower guide 40 is arranged, in use, between said intermediate guide and the device under test.

In the embodiment of FIG. 1, the probe head 20 may further comprise an upper guide 45 separated from the lower guide 40 and equipped with respective guide holes 45h. Should there also be the intermediate guide, said intermediate guide is arranged between the lower guide 40 and the upper guide 45, wherein the lower guide 40 is still the closest guide to the device under test.

As mentioned above and as conventional in the technical field of the present invention, the term “lower guide” thus indicates the guide which is arranged closer to a device under test and the term “upper guide” indicates the guide which is arranged closer to a testing apparatus connected to the probe head, when said probe head 20 is in the operating conditions, mounted as end element of said testing apparatus.

In an embodiment, the lower guide 40, the upper guide 45 and the possible intermediate guide are plate-shaped elements arranged parallel to each other and to a plane π of the semiconductor wafer 23′ and thus of the device under test 23. Moreover it is noted that, in the context of the present invention, the plane in which the guide 40 lies is identified as plane α.

Said guides may be shifted with respect to each other, with respect to a direction that is tangential to the plane π of the semiconductor wafer 23′ namely according to the x axis of the local reference of FIG. 1, so as to impose a preferential bending direction to the contact probes 10. Due to this shift of the guides, the guide holes formed therein and housing a same contact probe turn out not to be aligned to each other with respect to a direction orthogonal to the plane π of the semiconductor wafer 23′, namely according to the z axis of the local reference of FIG. 1, which forces a bending in the probe body 10′ of the contact probes 10 and determines said preferential bending direction thereof.

The probe head 20 further comprises a housing or housing element 50 configured to house the contact probes 10 and to also provide a support and connection structure between the guides.

In particular, the housing 50 comprises a body (identified with reference number 50′) configured to contain the contact probes 10), said body 50′ being preferably monobloc-shaped.

In the embodiment of FIG. 1, the housing 50 is interposed between the lower guide 40 and the upper guide 50 and causes the suitable distancing therebetween, said housing 50 being suitably shaped to house the contact probes 10 therein.

The housing 50 may be made of a material suitable for controlling the thermal expansion of the probe head, for instance selected from invar or covar, however without this limiting the scope of the present invention; indeed, any suitable material may be used.

Suitably, the housing 50 comprises conveying means (generally indicated with reference M) for conveying an air flow (generated externally and indicated in the figures with the arrow F) adapted to facilitate a heat dissipation inside the probe head 20. Therefore there is a conveying system for conveying forced air configured to convey an air flow into the housing 50, thus facilitating the dissipation of the heat generated by the probe head 20.

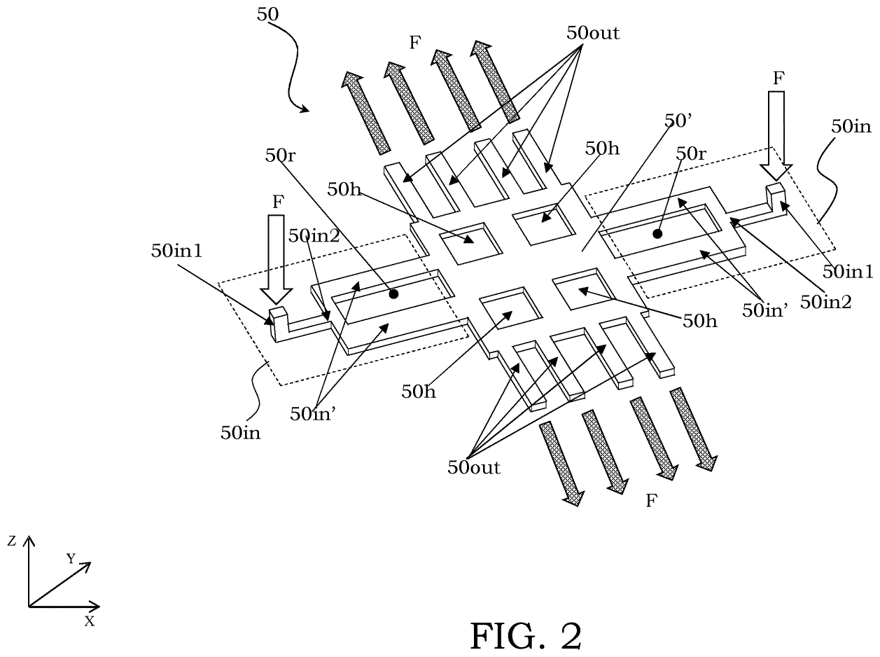

As illustrated in FIG. 2, the conveying means of the housing comprise at least one input duct 50in configured to receive the air flow F from an external source (not illustrated) and to allow conveying said air flow F into the housing 50, as well as at least one output duct 50out configured to cause said air flow F to flow out of the housing 50.

The input duct 50in is thus configured so that the air coming from the external source, in particular coming from the side where there is the testing apparatus and thus opposite the wafer 23′, is guided toward the guide 40 and possibly split by a bifurcation of said duct (as it will be seen later). The number of the input ducts 50in (as well as the number of bifurcations of each of said ducts) may vary according to the number of dies to be tested through the probe head 20 (for instance, four dices tested in parallel as it will be discussed hereinafter in the examples).

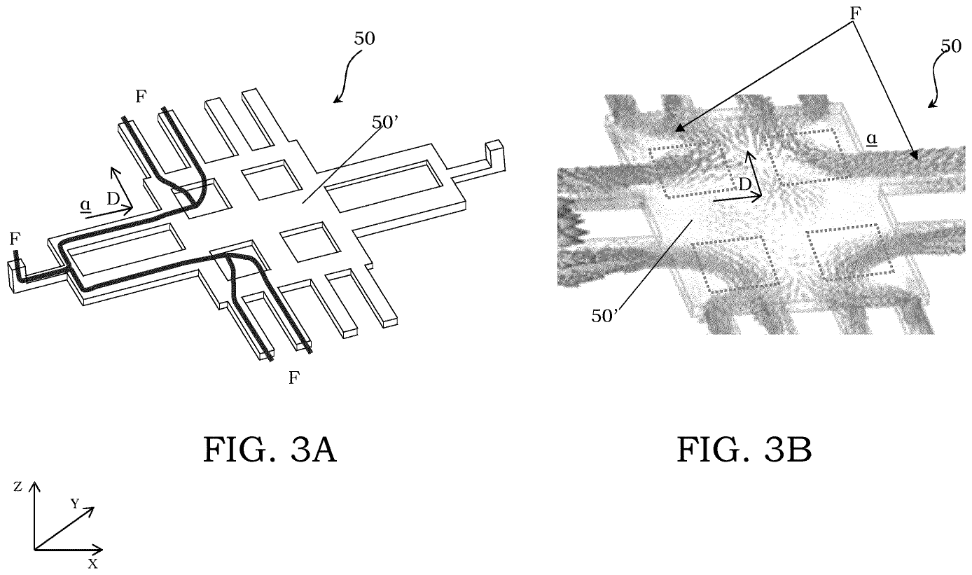

In an embodiment, the input ducts 50in and the output ducts 50out are oriented so that the air flow F propagates inside housing 50 according to a flow direction (indicated with the arrow D in FIGS. 3A and 3B) which lies in a plane that is substantially parallel to the plane α of the guide 40. In this way, the channels of the housing 50 ensure an air flow F that is substantially tangential to the guide 40 of the probe head 20.

The input 50in and output ducts 50out are thus advantageously formed inside the housing 50, in particular there are channels internal to the housing 50 and portions formed integral therewith. In this way, further components are not added and the probe head 20 maintains a very compact structure.

As illustrated in FIGS. 2 and 3A-3B, in an embodiment of the present invention, for each input duct 50in there are at least two output ducts 50out, so that the air flow F exiting from the housing 50 is divided into at least two flow portions; clearly even a different number of output ducts may be provided based on the specific applications.

All this ensures a uniform air flow and on an extend area, as it may be noted in the simulation of FIG. 3C, and thus an optimal dissipation inside the probe head 20.

According to the present invention, the contact probes 10 are included in at least one first area or active area (indicated with reference A1) of the guide 40. It is thus possible to also define second area (indicated with reference A2) of said guide 40 which does not include the contact probes 10, said second area A2 being adjacent (contiguous) to said active area A1. Obviously the above areas are not limited by a particular shape; for instance, the second area A2 may be an area surrounding the active area A1, just as there may be more than one active area on the guide (as it will be illustrated herein below).

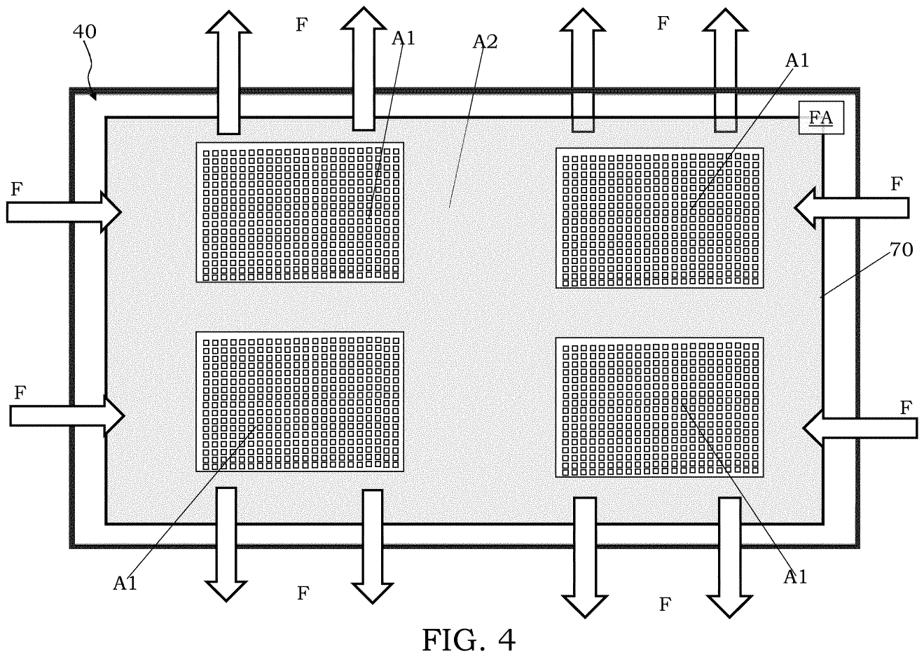

In an embodiment of the present invention, as schematically illustrated in FIG. 4, the guide 40 may comprise a plurality of distinct active areas A1, each of said active areas A1 comprising a respective group of contact probes 10 and being configured for the test of a relevant die on which the circuitry to be tested is formed (in the figure, the single dies have a rectangular shape but this is not necessary and even other shapes are not excluded).

Suitably, the active areas A1 are thus arranged so as to allow a test in parallel of a plurality of dices (and thus a multi-dice test in parallel), wherein each of said active areas A1 corresponds to a related die to be tested. In this example, the second area A2 is that area of the guide 40 which does not include the probes and which surrounds the various active areas A1 and, thus, does not include any die.

In this case, as already mentioned above, the input duct 50in may comprise a plurality of input sub-ducts (indicated with reference 50in′) adapted to divide the input air flow F and to convey it toward a respective active area A1. FIGS. 2, 3A-3B, and 4 show an example in which two input ducts 50in are both split into two input sub-ducts 50in′ to send the air flow F toward a respective die, said input sub-ducts 50in′ being separated by a recess 50r.

In general, the number of input sub-ducts 50in′ may be selected based on the number of dies to be tested through the probe head 20, and thus based on the layout and the specific application. Moreover, as also previously described, in an embodiment the output ducts 50out ensure that, for each single die, there are at least two air outlet paths, which extend substantially parallel to the guide 40.

Furthermore, though FIG. 4 shows an example in which four active areas A1 are present, the present invention is not limited thereto and the number of active areas may vary based on the application, the figures being provided just by way of non-limiting example of the present invention.

In an embodiment, the distinct active areas A are arranged on the guide 40 along respective rows and columns in a matrix configuration, for instance a 4×4 matrix as seen in connection with FIG. 4, wherein the layout on the guide follows the layout of the devices under test and/or of the wafer.

Moreover it is noted that, though the above embodiments are illustrated in connection with the lower guide 40, the same reasoning may be applied to any other guide of the probe head 20.

As illustrated, there are also openings 50h formed in the housing 50 at the various active areas A1 for the passage of the contact probes 10 intended to test the corresponding die.

Still with reference to FIG. 2, in an embodiment of the present invention the input duct 50in comprises a first portion 50in1 and a second portion 50in2 angled toward each other, for instance orthogonal to each other. In particular, the first portion 50in1 (vertical portion) is adapted to connect with the external source which the air flow F comes from, whereas the second portion 50in2 (horizontal portion) is in direct communication with the inside of the housing 50 and for instance is parallel to the guide 40. Both the first portion 50in1 and the second portion 50in2 may be seen as distinct portions of the same input duct 50in, which is suitably connectable (for instance at an opening in the vertical portion thereof) through means of the external source coming from the tester side, such as for instance tubes or similar means of the external source.

Furthermore, the input ducts 50in and the output ducts 50out extend on consecutive sides of the body 50′ of the housing 50.

In the embodiment of the figures, in order to direct the flow where desired in the most suitable manner, the output ducts 50out are substantially orthogonal to the input ducts 50in, at least in connection to portions thereof which lie in the plane α (for instance the above portions extending from the body 50′ of the housing 50).

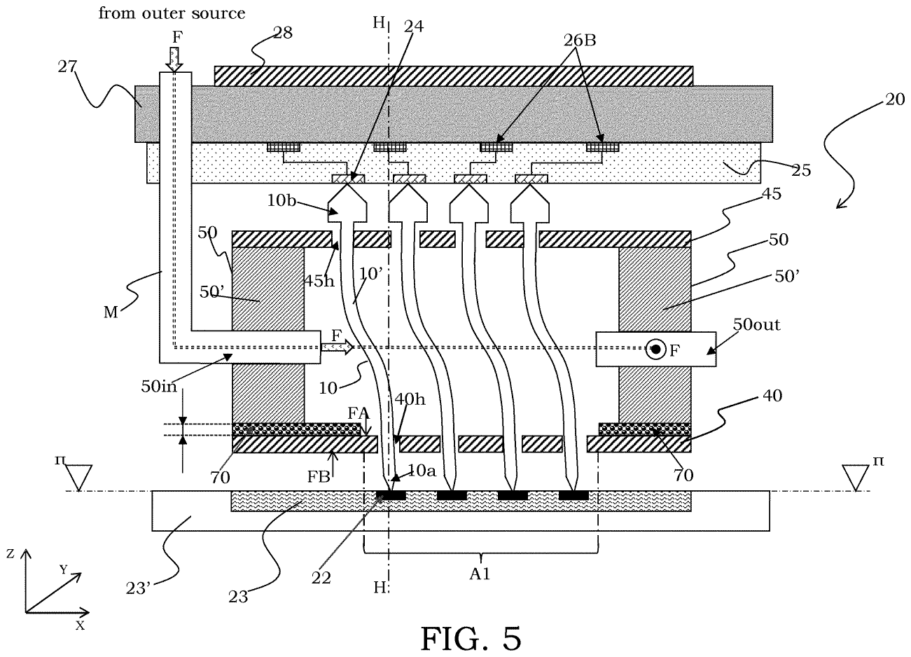

As illustrated in FIGS. 5 to 7, in an embodiment of the present invention, the probe head 20 further comprises a heat dissipation element (indicated with reference 70) adapted to collect and dissipate the heat produced during the test, preferably through dissipation in the air, and thus so as to make the dispersion and cooling process even more effective. The heat dissipation element 70 collects the heat generated for instance due to the friction of the contact probes sliding in the guide holes of at least one of the guides comprised in the probe head or due to the signals that pass through said contact probes and that may raise the temperature, for instance power signals, and facilitates the dispersion in the environment, preferably through dissipation in the air.

The heat dissipation element 70 thus has at least one portion in contact with the air, even for instance with the environment surrounding the probe head 20.

In an embodiment, the heat dissipation element 70 comprises at least one layer of high thermal conductivity material (still indicated with reference number 70), for instance selected from diamond, silicon carbide and silver-diamond compound with a diamond percentage between 50 and 99%, preferably diamond. Said high thermal conductivity allows obtaining an optimal collection and subsequent dispersion of the heat produced by the probe head 21 during the testing operations, thus maintaining the increase in operating temperature limited. Moreover the above indicated materials allow making structures with reduced thicknesses Sr, in particular below 500 microns, more preferably below 250 microns, while maintaining the heat dissipation properties of the thus obtained dissipative structures high.

In the embodiment illustrated in FIG. 5, the layer of high thermal conductivity material 70 is formed at a face of the guide 40 for instance on a face FA thereof (for instance, it may only coat a portion or entirely said face, without limiting the scope of the present invention). However the present invention is not limited by the arrangement of the dissipation layer 70 on the guide, which may be arranged both on the face FA, which is an upper face, and on the opposite lower face FB thereof (using the local reference of the figure and the terminology commonly used in the technical field of the invention), and possibly only on the lower face FB; when it is also arranged on the lower face FB thereof, the layer of high thermal conductivity material 70 is exposed to the environment surrounding the probe head 20, thus facilitating the dissipation of the heat produced therein in the air.

In an embodiment not illustrated in the figures, the layer of high thermal conductivity material 70 may be a covering layer of the guide 40 which comprises at least one lateral portion extending along a lateral wall of the guide 40 and at least one planar portion extending along at least one face (F1 and/or F2) of said guide 40, said face (F1 and/or F2) being substantially orthogonal to said lateral wall.

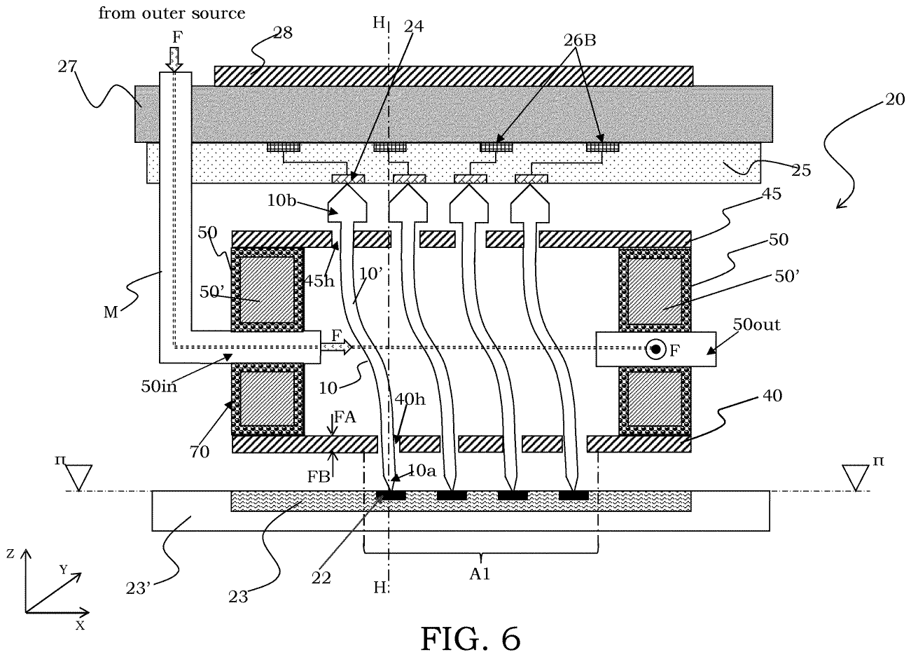

In the embodiment of FIG. 6, the dissipation layer is a layer associated with the housing 50, for instance a full covering layer of said housing 50 even if, in embodiments not illustrated, it may also be a lateral layer.

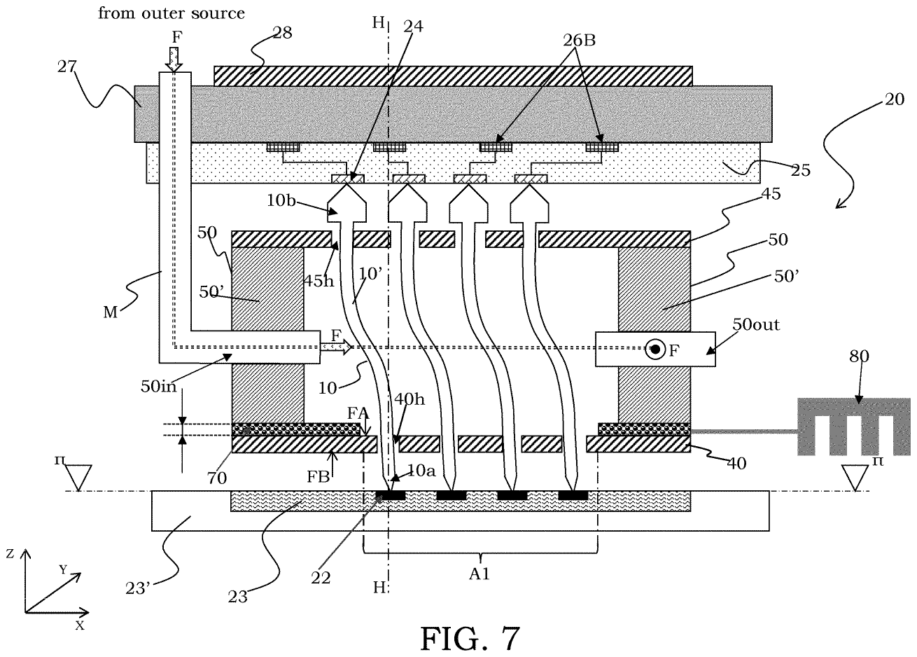

Furthermore, in the embodiment illustrated in FIG. 7, the probe head 20 may also comprise a dissipation structure 80 connected to the layer of high thermal conductivity material 70. It is pointed out that in this case the layer of high thermal conductivity material 70 essentially provides collecting the heat produced inside the probe head 20 whereas the dissipation structure 80 is mainly responsible for the dissipation thereof, preferably in the air. For instance, the dissipation structure 80 may be comb-shaped, namely may be equipped with a plurality of wings able to increase the heat dissipation.

The layer of high thermal conductivity material 70 extends out of the active area A1 (but possibly also inside) on the entire face of the guide 40 or also only on portions thereof; in some embodiments, as seen above, it may also comprise lateral portions to wind (entirely or partially) said guide 40 and possibly also the housing 50. In any case, it extends so as to facilitate the heat exchange with the air, and thus with the air flow F as well. In this way, the combination of the air flow F with the layer of high thermal conductivity material 70 ensures an even more effective dissipation also thanks to its high conductivity.

Furthermore, in an embodiment not illustrated in the figures, it is possible to envisage a plurality of layers of high thermal conductivity material 70, based on the circumstances and/or needs.

Once again it is noted that, though the above embodiments are illustrated in connection to the lower guide 40, the same reasonings may be applied to any other guide of the probe head 20.

Suitably, the layer of high thermal conductivity material 70 is arranged so that the air flow F of the conveying means M passes at the same, said air flow F thus facilitating the dissipation of the heat exchanged by said layer of high thermal conductivity material 70.

In particular, as above mentioned, the layer of high thermal conductivity material 70 extends in at least one part of the second area A2, and the conveying means M are configured to convey the air flow F so as to hit said layer of high thermal conductivity material 70 in the second area A2 where the contact probes 10 are not present and to facilitate the heat dissipation in said area. In other words, the layer of high thermal conductivity material 70 is preferably arranged outside the active area of the guide 40, in particular a peripheral area where the guide holes are not present.

In conclusion, to sum up the above, the present invention thus allows overcoming the technical problem, by providing the above probe head and solving all of the prior art drawbacks.

Suitably, the cooling of the probe head occurs thanks to the channels of the housing, which guide and force the air flow thereinto in the most suitable manner. The various input and output ducts are arranged so that the air flow spreads in the most homogeneous manner in the areas of interest of the probe head. In other terms, the housing is shaped so that the air conveying system is formed precisely in said housing, namely the air conveying system is part of the housing 50 itself (which thus may be seen as the body of said system, shaped so as to allow to suitably convey air into the probe head). The air is generated by an air external source (not illustrated) which is associable with the probe head and which then conveys said air thereinto, in particular by means of the above ducts.

Advantageously according to the present invention, a heat dissipation structure is formed which is able to collect and dissipate the heat generated during the testing operations of the probe head, for instance generated due to the friction of the contact probes sliding in the guide holes or due to the signals passing through said contact probes and that may increase the temperature thereof (for instance power signals). Such heat dissipation structure also facilitates the dispersion of said heat into the environment, in particular by dissipation in the air through a forced air flow.

Therefore this solution allows a suitable forced air conveying and is advantageous even for devices with multiple dices tested in parallel.

The conveying means of the housing, possibly in combination with the layer of high thermal conductivity material, thus suitably limit the increase in the operating temperature of the probe head, avoiding malfunctions in a simple way.

The combination of the forced air flow with the above layer of high thermal conductivity material is particularly advantageous, since said air flow allows the dissipation in the air of the heat produced by the probe head and collected by said layer of high thermal conductivity material already inside the probe head itself. The heat dispersion is indeed further improved, since often the air flow alone is not enough to disperse the heat generated at the innermost contact probes, which are not greatly affected by said air flow that indeed only hits the outermost probes.

In this way, the probe head according to the present invention turns out to be suitable for applications in which the testing operation significantly heats the head as a whole, ensuring a correct operation thereof and thus the good outcome of the test.

All this is also achieved through a simple and compact structure, since the various input and output ducts are directly formed in the body of the housing, which thus is shaped in the most suitable manner for conveying the cooling air flow.

Obviously, a person skilled in the art, in order to meet contingent and specific requirements, may make to the above-described probe head numerous modifications and variations, all included in the scope of protection of the invention as defined by the following claims.

1. A probe head for testing a device under test, comprising:
a plurality of contact probes comprising a body extending along a longitudinal axis between a first end portion and a second end portion, said end portions being adapted to contact respective pads;
a guide provided with guide holes for housing portions of the contact probes, said guide lying in a plane; and
a housing comprising a body configured to contain the contact probes;
wherein the housing comprises conveying means for conveying an air flow, said conveying means being adapted to facilitate a heat dissipation inside the probe head, said conveying means including:
an input duct configured to receive the air flow and to allow conveying said air flow into the housing; and
an output duct configured to cause the air flow to flow out of the housing,
wherein the input ducts and output duct are formed in the body of the housing.

2. The probe head according to claim 1, wherein the input duct and the output duct are oriented so that the air flow propagates inside the housing according to a flow direction which is substantially parallel to the plane of the guide.

3. The probe head according to claim 1, comprising, for each input duct, at least two output ducts so that the air flow exiting from the housing is divided into at least two flow portions.

4. The probe head according to claim 1, further comprising a heat dissipation element adapted to collect and dissipate heat produced by said probe head, said heat dissipation element being arranged so that the air flow of the conveying means passes at the same, said air flow thus facilitating the dissipation of the heat exchanged by said heat dissipation element.

5. The probe head according to claim 4, wherein the heat dissipation element comprises a layer of high thermal conductivity material selected from diamond, silicon carbide and a silver-diamond compound with a diamond percentage between 50 and 99%.

6. The probe head-according to claim 5, wherein said layer of high thermal conductivity material is one of:
a coating layer arranged along a part of at least one face of the guide; or
a guide covering layer that comprises a lateral portion extending along a lateral wall of said guide, and a planar portion extending along a part of a face of said guide, said face being substantially orthogonal to said side wall; or
a coating layer associated with the housing.

7. The probe head according to claim 1, wherein the contact probes are included in a first area or active area of the guide, said active area being contiguous to a second area of said guide that does not include the contact probes.

8. The probe head according to claim 5, wherein the layer of high thermal conductivity material extends in a part of the second area, and wherein the conveying means are configured to convey the air flow so as to hit said layer of high thermal conductivity material at said part of the second area.

9. The probe head according to claim 7, wherein the guide comprises a plurality of distinct active areas each of said active areas comprising respective contact probes and being configured for testing a respective die, said active areas being arranged to allow a multi-die test in parallel, wherein each of said active areas corresponds to a respective die under test, and wherein the input duct comprises a plurality of input sub-ducts adapted to divide the input air flow and to convey the same toward a respective active area, the number of input sub-ducts being selected based on the number of device to be tested by means of said probe head.

10. The probe head according to claim 9, wherein the active areas are arranged on the guide along respective rows and columns in a matrix configuration, for instance a 4×4 matrix.

11. The probe head according to claim 1, wherein the guide is a lower guide, and wherein said probe head further comprises an upper guide separated from the lower guide and provided with respective guide holes, the housing being arranged between the lower guide and the upper guide.

12. The probe head according to claim 1, wherein the input duct comprises a first portion and a second portion angled toward each other, said first portion being adapted to connect to an external source wherefrom the air flow comes, said second portion being in communication with the inside of the housing.

13. The probe head according to claim 1, wherein the input duct and the output duct extend from consecutive sides of the body of the housing.

14. The probe head according to claim 1, wherein the input ducts and output ducts are substantially orthogonal to each other in the plane of the guide, at least in relation to portions thereof lying in said plane.

15. The probe head according to claim 1, wherein the body of the housing is in the shape of a monobloc, and wherein the input ducts and output ducts are formed in said monobloc and comprise portions formed integrally therewith.

16. The probe head according to claim 5, wherein the high thermal conductivity material is diamond.
